(19) United States
(12) Patent Application Publication
(10) Pub. No.: US 2025/0123651 A1
(43) Pub. Date: Apr. 17, 2025

(54) METHOD, A MEMORY SYSTEM AND AN ELECTRONIC DEVICE

(71) Applicant: YANGTZE MEMORY TECHNOLOGIES CO., LTD., Wuhan (CN)

(72) Inventor: Xi WANG, Wuhan (CN)

(21) Appl. No.: 18/893,236

(22) Filed: Sep. 23, 2024

(30) Foreign Application Priority Data
Oct. 13, 2023 (CN) 2023113372105

(51) Int. Cl. G06F 1/08; G11C 5/14

(52) U.S. Cl. CPC G06F 1/08; G11C 5/14

(57) ABSTRACT

The present disclosure provides a method, a memory system and an electronic device for adjusting sampling frequency, and relates to the field of semiconductor chip technology. The method includes: obtaining an impact element for thermal sampling of a target device; adjusting the sampling frequency of the thermal throttling module corresponding to the target device in accordance with the impact element for thermal sampling. The present disclosure intends to improve the problem of being unable to effectively adjust the sampling frequency of the thermal throttling module corresponding to critical system components in the solid-state drive.

### CROSS-REFERENCE TO RELATED APPLICATIONS

The present application claims priority to Chinese Patent Application No. 2023113372105, which was filed Oct. 13, 2023, is titled “A SAMPLING FREQUENCY ADJUSTMENT METHOD, STORAGE SYSTEM AND ELECTRONIC EQUIPMENT,” and is hereby incorporated herein by reference in its entirety.

### TECHNICAL FIELD

The present disclosure relates to the field of semiconductor chip technology, and in particular, to a method, a memory system and an electronic device for adjusting sampling frequency.

### BACKGROUND

As the bus speed increases, the read and write performance of Solid-State Drive (SSD) has also been significantly improved. When a solid-state drive responds to a large number of IO requests, the temperatures of its critical system components may rise.

### SUMMARY

Examples of the present disclosure provide a method, a memory system and an electronic device for adjusting sampling frequency, which intend to solve the problem that the sampling frequency of the thermal throttling module corresponding to critical system components in the solid-state drive is difficult to be effectively adjusted.

For the above purpose, examples of the present disclosure employ the following technical solutions:

In a first aspect, a method for adjusting sampling frequency is provided, the method includes: obtaining an impact element for thermal sampling of a target device; adjusting the sampling frequency of the thermal throttling module corresponding to the target device in accordance with the impact element for thermal sampling.

The method for adjusting sampling frequency provided by the present disclosure may be capable of automatically adjusting the sampling frequency of the thermal throttling module in accordance with the impact element for thermal sampling of the target device. Thus, when the solid-state drive responds to a large number of IO requests, temperature monitoring and thermal throttling may be dynamically optimized to more effectively maintain the stability of system. Secondly, adjusting the sampling frequency through the impact element for thermal sampling may monitor and respond to temperature changes inside the solid-state drive more accurately, which helps reduce the potential impact of high temperatures on the solid-state drive and reduces the possibility of data damage and data loss.

In some examples, the impact element for thermal sampling includes the temperature of the target device and an impact factor in at least one dimension; and the adjusting the sampling frequency of the thermal throttling module corresponding to the target device in accordance with the impact element for thermal sampling includes: determining a basic sampling frequency in accordance with the temperature of the target device; determining the adjustment amount for sampling frequency in accordance with the impact factor in at least one dimension; adjusting the sampling frequency of the thermal throttling module corresponding to the target device to the target sampling frequency in accordance with the basic sampling frequency and the adjustment amount for sampling frequency, wherein the target sampling frequency is equal to the sum of the basic sampling frequency and the adjustment amount for sampling frequency.

The method for adjusting sampling frequency provided by the present disclosure determines the basic frequency of sampling for the thermal throttling module based on the temperature of the target device, and determines the adjustment amount for sampling frequency of the thermal throttling module based on the impact factor, thereby enabling more precise and reliable adjustment of the sampling frequency, and thereby improving the response speed and response accuracy of the thermal throttling module.

In some examples, determining a basic sampling frequency in accordance with the temperature of the target device includes: determining the basic sampling frequency to be a first sampling frequency when the temperature of the target device is within a first temperature interval; determining the basic sampling frequency to be a second sampling frequency when the temperature of the target device is within a second temperature interval, wherein the temperature in the first temperature interval is lower than the temperature in the second temperature interval, and the first sampling frequency is lower than the second sampling frequency.

According to the method for adjusting sampling frequency provided by this disclosure, since the target device operating under high temperature conditions is easily affected, e.g., potential malfunctions or data corruption, etc., in high temperature conditions, the thermal throttling module may increase the sampling frequency, and increasing the sampling frequency may ensure that temperature changes may be detected in time, and potential high temperature problems may be more sensitively sensed, and thus there is an opportunity to take necessary measures to reduce the risk of target device malfunctions.

In some examples, the determining the adjustment amount for sampling frequency in accordance with the impact factor in at least one dimension includes: obtaining the first adjustment amount in each dimension in accordance with the impact factor in each dimension of the at least one dimension; determining the adjustment amount for sampling frequency in accordance with the first adjustment amount in each dimension and a weight coefficient corresponding to the dimension, wherein the adjustment amount for sampling frequency is equal to an accumulated value of the product of the first adjustment amount corresponding to each dimension of the at least one dimension and the corresponding weight coefficient.

In some examples, the target device includes a memory controller and a memory, wherein the impact factor of the memory controller includes a rate of temperature change, and the impact factor of the memory includes a rate of temperature change, a first position parameter, a second position parameter, the number of cycles of program/erase, the number of bad blocks and a type of stored data.

In some examples, the first position parameter is to represent a relative distance between the memory and the memory controller, and the second position parameter is to represent a relative distance between the memory and the high-temperature area in the electronic device.

In some examples, obtaining the first adjustment amount in each dimension in accordance with the impact factor in each dimension includes: increasing the first adjustment amount corresponding to the rate of temperature change when the rate of temperature change increases.

In some examples, obtaining the first adjustment amount in each dimension in accordance with the impact factor in each dimension further includes: increasing the first adjustment amount corresponding to the first position parameter when the first position parameter decreases.

In some examples, obtaining the first adjustment amount in each dimension in accordance with the impact factor in each dimension further includes: increasing the first adjustment amount corresponding to the second position parameter when the second position parameter decreases.

In some examples, obtaining the first adjustment amount in each dimension in accordance with the impact factor in each dimension further includes: increasing the first adjustment amount corresponding to the number of cycles of program/erase when the number of cycles of program/erase increases.

In some examples, obtaining the first adjustment amount in each dimension in accordance with the impact factor in each dimension further includes: increasing the first adjustment amount corresponding to the number of bad blocks when the number of bad blocks increases.

In some examples, obtaining the first adjustment amount in each dimension in accordance with the impact factor in each dimension further includes: increasing the first adjustment amount corresponding to the type of stored data when the type of stored data is hot data.

In a second aspect, a memory system is provided, wherein the memory system includes: a memory and a memory controller; the memory controller is coupled to the memory, and the memory controller is configured to: obtain an impact element for thermal sampling of a target device; adjust the sampling frequency of the thermal throttling module corresponding to the target device in accordance with the impact element for thermal sampling.

In some examples, the impact element for thermal sampling includes the temperature of the target device and an impact factor in at least one dimension, the memory controller is configured to: determine a basic sampling frequency in accordance with the temperature of the target device; determine the adjustment amount for sampling frequency in accordance with the impact factor in at least one dimension; adjust the sampling frequency of the thermal throttling module corresponding to the target device to the target sampling frequency in accordance with the basic sampling frequency and the adjustment amount for sampling frequency, wherein the target sampling frequency is equal to the sum of the basic sampling frequency and the adjustment amount for sampling frequency.

In some examples, the memory controller is configured to: determine the basic sampling frequency to be a first sampling frequency when the temperature of the target device is within a first temperature interval; determine the basic sampling frequency to be a second sampling frequency when the temperature of the target device is within a second temperature interval, wherein the temperature in the first temperature interval is lower than the temperature in the second temperature interval, and the first sampling frequency is lower than the second sampling frequency.

In some examples, the memory controller is configured to: obtain the first adjustment amount in each dimension in accordance with the impact factor in each dimension of the at least one dimension; determine the amount sampling for frequency adjustment in accordance with the first adjustment amount in each dimension and a weight coefficient corresponding to the dimension, wherein the adjustment amount for sampling frequency is equal to an accumulated value of the product of the first adjustment amount corresponding to each dimension of the at least one dimension and the corresponding weight coefficient.

In some examples, the target device includes a memory controller and a memory, wherein the impact factor of the memory controller includes a rate of temperature change, and the impact factor of the memory includes a rate of temperature change, a first position parameter, a second position parameter, the number of cycles of program/erase, the number of bad blocks and a type of hotness or coldness of stored data.

In some examples, the first position parameter is to represent a relative distance between the memory and the memory controller, and the second position parameter is to represent a relative distance between the memory and the high-temperature area in the electronic device.

In some examples, the memory controller is configured to: increase the first adjustment amount corresponding to the rate of temperature change when the rate of temperature change increases.

In some examples, the memory controller is further configured to: increase the first adjustment amount corresponding to the first position parameter when the first position parameter decreases.

In some examples, the memory controller is further configured to: increase the first adjustment amount corresponding to the second position parameter when the second position parameter decreases.

In some examples, the memory controller is further configured to: increase the first adjustment amount corresponding to the number of cycles of program/erase when the number of cycles of program/erase increases.

In some examples, the memory controller is further configured to: increase the first adjustment amount corresponding to the number of bad blocks when the number of bad blocks increases.

In some examples, the memory controller is further configured to: increase the first adjustment amount corresponding to the impact factor of the type of hotness or coldness of stored data when the stored data is hot data.

In a third aspect, an electronic device is provided, which includes a host and a memory system of any of items in the second aspect, the host being coupled with the memory system to write data to the memory system or read data stored in the memory system.

In a fourth aspect, a computer-readable storage medium is provided, the computer-readable storage medium stores computer-executable instructions; and the computer-executable instructions, after being executed, may implement the method of any items in the first aspect described above.

It may be understood that the technical effects of the second to fourth aspects refer to the technical effects of the first aspect and any of its examples, which will not be repeated here.

### BRIEF DESCRIPTION OF THE DRAWINGS

FIG. 1 is a schematic diagram of an electronic device provided by examples of the present disclosure;

FIG. 2 is a schematic diagram of a memory system provided by examples of the present disclosure;

FIG. 3 is a schematic diagram of another memory system provided by examples of the present disclosure;

FIG. 4 is a schematic flowchart of a method for adjusting sampling frequency according to the present disclosure;

FIG. 5 is a schematic flowchart of another method for adjusting sampling frequency according to the present disclosure;

FIG. 6 is a schematic flowchart of another method for adjusting sampling frequency according to the present disclosure;

FIG. 7 is a schematic diagram of the corresponding relationship between temperature and basic sampling frequency according to the present disclosure;

FIG. 8 is a schematic flowchart of another method for adjusting sampling frequency according to the present disclosure;

FIG. 9 is a schematic diagram of the corresponding relationship between an impact factor and the first adjustment amount according to the present disclosure;

FIG. 10 is a schematic diagram of the corresponding relationship between another impact factor and the first adjustment amount according to the present disclosure;

FIG. 11 is a schematic diagram of the corresponding relationship between another impact factor and the first adjustment amount according to the present disclosure;

FIG. 12 is a schematic diagram of the corresponding relationship between another impact factor and the first adjustment amount according to the present disclosure;

FIG. 13 is a schematic diagram of the corresponding relationship between another impact factor and the first adjustment amount according to the present disclosure;

FIG. 14 is a schematic diagram of the corresponding relationship between another impact factor and the first adjustment amount according to the present disclosure.

### DETAILED DESCRIPTION

The technical solutions in some examples of the present disclosure will be clearly and completely described below in conjunction with the accompanying drawings. The described examples are only some examples of the present disclosure. All other examples obtained by those skilled in the art based on the examples provided in the present disclosure belong to the scope of the present disclosure.

Unless the context requires otherwise, throughout the description and claims, the term “comprising” is interpreted as open and inclusive, i.e., “including, but not limited to”. In the description of the present disclosure, the terms “one example”, “some examples”, “exemplary example”, “in one example” or “some examples” are intended to indicate that a particular feature, structure, material, or characteristic related to the example or example is included in at least one example or example of the present disclosure. Illustrative representations of the terms described above are not necessarily referring to a same example or example. Furthermore, particular feature, structure, material or characteristic described above may be included in any suitable manner in any one or more examples or examples.

Hereinafter, the terms “first” and “second” are used for descriptive purposes only, and should not be understood as indicating or implying relative importance or implicitly specifying the quantity of indicated technical features. Thus, a feature defined as “first” and “second” may explicitly or implicitly include one or more of these features. In the description of examples of the present disclosure, “plurality” means two or more, unless specified otherwise.

In describing some examples, the expressions “coupling” and their derivatives may be used. For example, in describing some examples, the term “coupling” may be used to indicate that two or more elements are in direct physical or electrical contact, in this case, “coupling” may also be described as “connecting”. Additionally, the term “coupling” may also mean that two or more elements are not in direct contact with each other, but yet still co-operate or interact with each other. Examples disclosed herein are not necessarily limited by the context herein.

“At least one of A, B and C” has the same meaning as “at least one of A, B or C” and both include the following combinations of A, B and C: only A; only B; only C; combination of A and B; combination of A and C; combination of B and C; and combination of A, B and C.

“A and/or B” includes the following three combinations: only A; only B; only C; and combination of A and B. The use of “suitable for” or “configured to” herein means open and inclusive language that does not exclude devices that are suitable for or configured to perform additional tasks or operations. Additionally, the use of “based on” is meant to be open and inclusive, as a process, operation, calculation, or other action that is “based on” one or more conditions or values may in practice be based on additional conditions or beyond values.

The use of “configured to” herein means open and inclusive language that does not exclude devices that are suitable for or configured to perform additional tasks or operations.

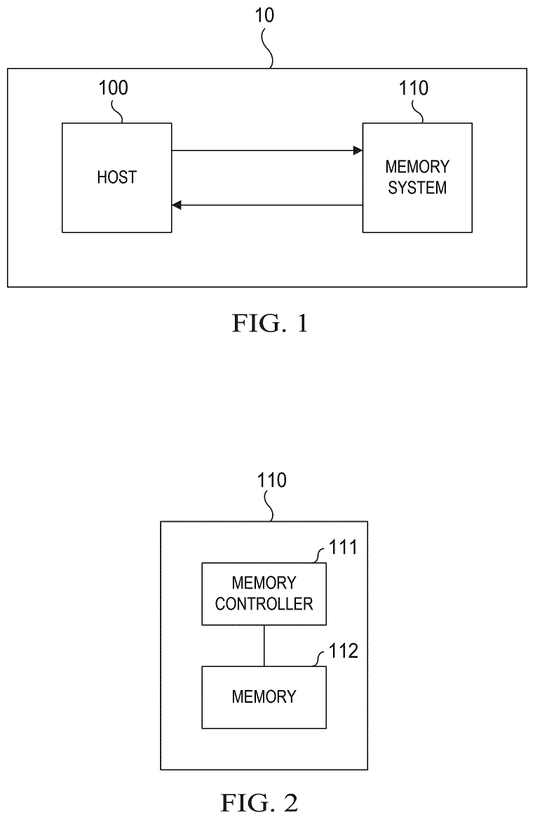

An example of the present disclosure provides an electronic device, which may be e.g., any one of mobile phone, desktop computer, tablet computer, notebook computer, server, vehicle-mounted device, wearable device (e.g., smart watch, smart bracelet, smart glasses, etc.), mobile power supply, game console, digital multimedia player, etc. Referring to FIG. 1, FIG. 1 shows a schematic diagram of an electronic device 10 provided by an example of the present disclosure, which includes a host 100 and a memory system 110, the host 100 is coupled with the memory system 110 to write data to the memory system 110 or read data stored in the memory system 110, where the host is also referred to as a master device, and the memory system is also referred to as a slave device, and in electronic devices, slave devices may be accessed by different master devices, e.g., taking the electronic device being a mobile phone as an example, central processing unit (CPU), digital signal processing (DSP), etc., of a mobile phone may each serve as a host to access the memory system.

For example, referring to FIG. 2, FIG. 2 shows a schematic diagram of a memory system 110 provided by an example of the present disclosure, the memory system 110 includes a memory controller 111 and a memory 112, and the memory controller 111 is coupled to the memory 112 to control the memory 112 to store data. The memory 112 may be a 2-dimension (2D) memory or a 3-dimension (3D) memory.

The memory system 110 may be integrated into various types of storage devices, e.g., included in a same package (e.g., universal flash storage (UFS) package or embedded multi media card (eMMC) package). That is to say, the memory system 110 may be applied to and packaged in different types of electronic products, e.g., a mobile phones (e.g., a cell phone), a desktop computer, a tablet computer, a notebook computer, a server, a vehicle-mounted device, a game console, a printer, a positioning device, a wearable device, a smart sensor, a power bank, a virtual reality (VR) device, an augmented reality (AR) device, or any other suitable electronic device with memory therein.

In some examples, the memory system 110 includes a memory controller 111 and a memory 112, and the memory system 110 may be integrated into a memory card. Memory card includes any one of personal computer memory card international association (PCMCIA) card (abbreviated as PC card), compact flash (CF) card, smart media (SM) card, memory stick, multi media card (MMC), secure digital memory card (SD) card, and UFS.

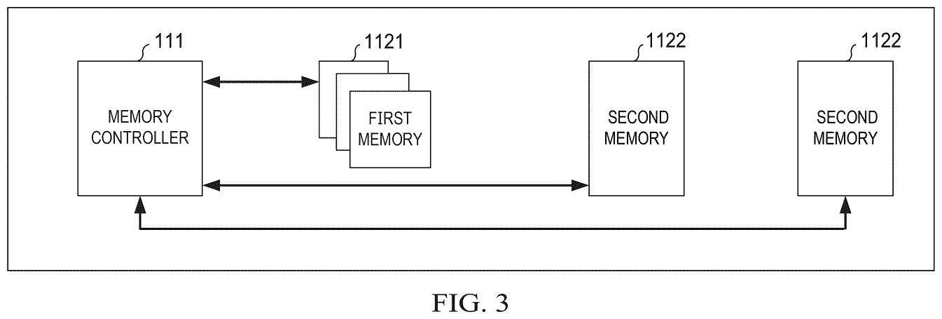

In other examples, referring to FIG. 3, the memory system 110 includes a memory controller 111, a first memory 1121 and a second memory 1122, and the memory system 110 is integrated into a solid-state drive (SSD).

In the memory system 110, in some examples, the memory controller 111 is configured to operate in a low duty cycle environment, e.g., a SD card, CF card, universal serial bus (USB) Flash drive or other media used in an electronic device such as a personal calculator, a digital camera, a mobile phone, etc.

In other examples, memory controller 111 is configured to operate in a high duty cycle environment SSD or eMMC, where a SSD or eMMC is used for data memory of mobile devices such as a smartphone, a tablets, a laptop, and an enterprise storage array.

In some examples, memory controller 111 may be configured to manage data stored in the first memory 1121 and the second memory 1122 and communicate with an external device (e.g., host 100). In some examples, memory controller 111 may also be configured to control operations of the first memory 1121 and the second memory 1122, e.g., read, erase, and program operations. In some examples, the memory controller 111 may be further configured to manage various functions related to data stored or to be stored in the first memory 1121 and the second memory 1122, including at least one of bad block management, garbage collection (GC), logical-to-physical address translation, wear leveling, etc.

Additionally, the memory controller 111 may communicate with an external device (e.g., host 100) through at least one of various interface protocols. It should be noted that an interface protocol includes at least one of universal serial bus (USB) protocol, Microsoft management console (MMC) protocol, peripheral component interconnect, PCI protocol, peripheral component interconnect express (PCI-E) protocol, advanced technology attachment (ATA) protocol, serial ATA protocol, parallel ATA protocol, small computer system interface (SCSI) protocol, enhanced small disk interface (ESDI) protocol, integrated drive electronics (IDE) protocol, and firewire protocol.

For a solid-state drive, when responding to a large number of IO requests, its internal target device such as a memory controller, dynamic random access memory (DRAM) and NAND flash will perform frequent read operations and write operations. These operations will cause the current and power consumption of the device to increase, thereby causing the temperature of the memory controller, random access memory, and NAND flash to rise significantly. And because the internal space of solid state drive is relatively small, heat accumulation may be more significant. Therefore, how to ensure the safety of the target device inside the solid-state drive when the internal temperature continues to rise is a critical concern.

One possible implementation is to provide protection for the target device of the solid-state drive through the thermal throttling module in the firmware, a temperature sensor is installed inside or outside the target device, and the thermal throttling module monitors the temperatures of individual target devices of the solid-state drive by obtaining the data collected by the temperature sensors of individual target devices, that is, the thermal throttling module may be divided into different functional areas, and different functional areas are responsible for monitoring corresponding target device, therefore, different functional areas of the thermal throttling module may be regarded as various corresponding thermal throttling modules for different target devices. Once the temperature reaches a set threshold, the thermal throttling module automatically limits the read and write speed of the solid state drive to reduce the heat generation of the component. By reducing the read and write bandwidth, workload of the solid-state drive is reduced and the temperatures of individual components are reduced.

The thermal throttling module requires to continuously monitor the operating temperature of these target devices to ensure that the target devices are in a normal operating state. One possible implementation is to employ a fixed sampling frequency to monitor the operating temperature of the target device, however, employing a fixed sampling frequency may not meet demands of different target devices, resulting in a situation where the sampling frequency is too high or the sampling frequency is too low.

When the sampling frequency of the thermal throttling module is too high, it may increase the occupation of hardware resources and lead to a decrease in memory system performance. Because the thermal throttling module needs to frequently monitor the hardware temperature at a higher sampling frequency, which may consume computing resources and power consumption. Therefore, employing a sampling frequency that is too high may cause the memory system to become slow, delay response and reduce data throughput.

When the sampling frequency of the thermal throttling module is too low, the thermal throttling module may not detect the rise or fall of temperature in time, therefore delaying the time for taking protective measures. In a high temperature environment, overheating of the target device may create the risk of insufficient data integrity. A sampling frequency that is too low means that the thermal throttling module may not respond quickly to the temperature rise of the target device, therefore increasing the probability of hardware failure and data corruption when the solid-state drive operates at a high temperature.

In summary, when employing a fixed sampling frequency to monitor the operating temperature of the target device, it may be unable to flexibly adapt to temperature changes under different workloads and environmental conditions. Because workloads and environmental conditions may change from time to time, a fixed sampling frequency may result in a too frequent or insufficient temperature sampling, therefore making it difficult for the memory system to accurately identify and respond to potential overheating issues.

Based on the context described above, how to reasonably adjust the sampling frequency of the thermal throttling module so as to protect the internal target device and data integrity of the solid-state drive more timely, is a critical concern of the industry.

One possible implementation is to dynamically adjust the sampling frequencies of the thermal throttling modules corresponding to individual target devices in accordance with different impact parameters for sampling frequency.

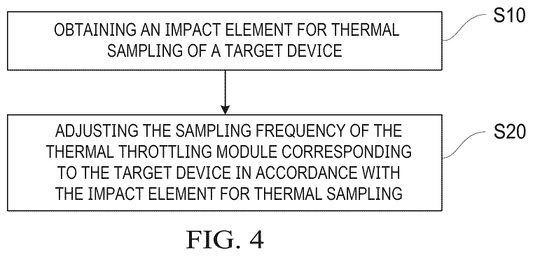

In one example, an example of the present disclosure provides a method for adjusting sampling frequency, referring to FIG. 4, the method includes:

S10: obtaining an impact element for thermal sampling of a target device.

The target device may be a critical system component in the solid-state drive, e.g., combined with FIG. 3, the target device includes a memory controller 111 and a memory 112, and the memory 112 includes a first memory 1121 and a second memory 1122, and in some implementations, the first memory 1121 includes a random-access memory and the second memory 1122 includes a NAND flash memory. An impact element for thermal sampling refers to a factor that may affect the sampling frequencies of the temperatures of the thermal throttling modules corresponding to the memory controller and memory, and these factors may be related to the location, function or other characteristics of the device. Different devices are affected by different factors, thus it is necessary to determine the corresponding adjustment strategy for sampling frequency in accordance with the characteristics of different target devices.

S20: adjusting the sampling frequency of the thermal throttling module corresponding to the target device in accordance with the impact element for thermal sampling.

In accordance with the impact element for thermal sampling of the memory controller and memory, the sampling frequency of the corresponding thermal throttling module is dynamically adjusted, so as to protect and optimize the performance of the solid-state drive, and the security and reliability of the data. Thus, a solid-state drive may perform adaptive performance management in accordance with different conditions, and provides higher performance and reliability, while hardware life is extended and the risk of failure is reduced, which in turn ensures that the solid-state drive may show an excellent performance under a variety of applications and workloads.

The scheme provided by examples of the present disclosure dynamically adjusts the sampling frequency of the thermal throttling module according to different impact elements for thermal sampling, so that the thermal throttling module may promptly identify potential temperature problems, thereby ensuring more timely protection of the target device inside the solid-state drive and ensuring data integrity. In addition, dynamically adjusting the sampling frequency may also reduce power consumption and heat generation and improve energy efficiency.

When the sampling frequency of the target device is being adjusted, the temperature of the target device itself is an important impact element, and its degree of impact is much greater than other impact elements, this is because the temperature of the target device itself is directly related to the stability, performance and lifespan of the hardware, thus special attention is required. Firstly, the temperature of the target device itself is one of the critical indicators of hardware health. Different target devices are very sensitive to the temperature of the device itself. A high temperature may cause the performance of electronic components inside the device to degrade or even be damaged, which may affect the reliability and lifespan of the device. Secondly, the temperature of the target device itself is a directly measurable parameter that may provide real-time information and therefore result in a significant advantage in adjustment for sampling frequency. In contrast, other potential impact elements may be more difficult to be accurately measured and monitored. Therefore, a basic sampling frequency may be determined in accordance with the temperature of the target device itself, and then the basic sampling frequency may be corrected based on other elements with less impact.

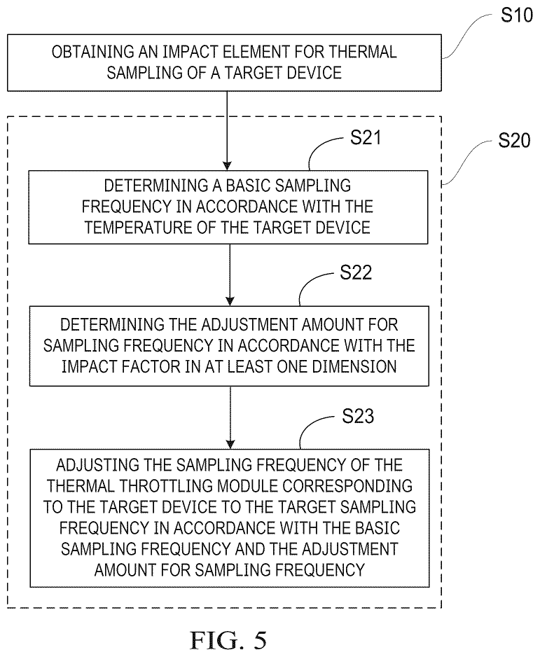

Referring to FIG. 5, in a possible implementation, S20 includes the following sub-operations:

S21: determining a basic sampling frequency in accordance with the temperature of the target device.

During the operation of the hardware device, heat may be generated, causing the temperature to rise, at this stage, the basic sampling frequency may increase as the temperature rises. When the temperature rises to be within the normal operating temperature range of the target device, it means that the target device is in a normal operating state, thus a fixed sampling frequency may be adapted for the target device. When the temperature continues to rise and exceeds the normal temperature operating range of the target device, it may have a greater impact on the reliability of the device. At this stage, more attention may be paid to the temperature of the target device, therefore the basic sampling frequency may increase as the temperature rises, and the changing trend of the basic sampling frequency may be faster.

S22: determining the adjustment amount for sampling frequency in accordance with the impact factor in at least one dimension.

Impact elements for thermal sampling include not only the temperature factor of the target device that has a major impact, but also some impact factors that have a secondary impact. An impact factor refers to various factors or variables that may affect the performance and operation of the target device. These impact factors may cause corresponding changes corresponding to the temperature of the device under different circumstances. Then, in accordance with the impact capabilities of these impact factors, the adjustment amount for sampling frequency by combining multiple impact factors is obtained.

S23: adjusting the sampling frequency of the thermal throttling module corresponding to the target device to the target sampling frequency in accordance with the basic sampling frequency and the adjustment amount for sampling frequency, wherein the target sampling frequency is equal to the sum of the basic sampling frequency and the adjustment amount for frequency.

After obtaining the adjustment amount for sampling frequency and the basic sampling frequency, the target sampling frequency is calculated through adding the basic sampling frequency and the adjustment amount for sampling frequency. The target frequency reflects the dynamically adjusted sampling frequency in accordance with the device temperature state (basic sampling frequency) and the impact factor (adjustment amount for sampling frequency). The calculated target sampling frequency is applied to the thermal throttling module to update the sampling frequency setting of the thermal throttling module, and the thermal throttling module collects the temperature information of individual target devices at a new frequency and responds to changes in device state in a timely manner.

As an example, the calculating formula of the target sampling frequency may be:

$$Ft = Fb + Δ F$$

in the formula, the basic sampling frequency is Fb, the adjustment amount for sampling frequency is ΔF, and the target sampling frequency is Ft.

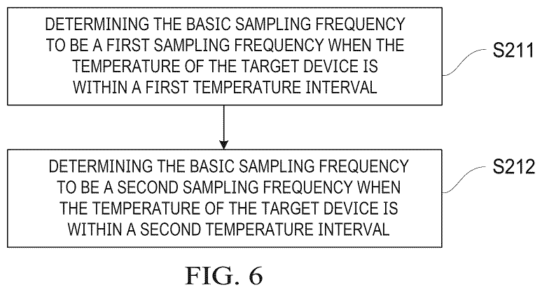

Referring to FIG. 6, in a possible implementation, S21 includes the following sub-operations:

S211: determining the basic sampling frequency to be a first sampling frequency when the temperature of the target device is within a first temperature interval;

S212: determining the basic sampling frequency to be a second sampling frequency when the temperature of the target device is within a second temperature interval; wherein the temperature in the first temperature interval is lower than the temperature in the second temperature interval, and the first sampling frequency is lower than the second sampling frequency.

The first temperature interval and the second temperature interval may be a temperature interval with a small range (e.g., 1° C. may be used as a temperature interval), or may be a temperature interval with a larger range (e.g., 10° C. may be used as a temperature interval), and the present disclosure does not limit the specific numerical magnitude of the temperature interval. The change of the basic sampling frequency of the target device from the first temperature interval to the second temperature interval reflects the trend that the basic sampling frequency of the target device increases with the increase of temperature, and it should be noted that the first temperature interval and the second temperature interval do not include the normal operating temperature interval of the target device.

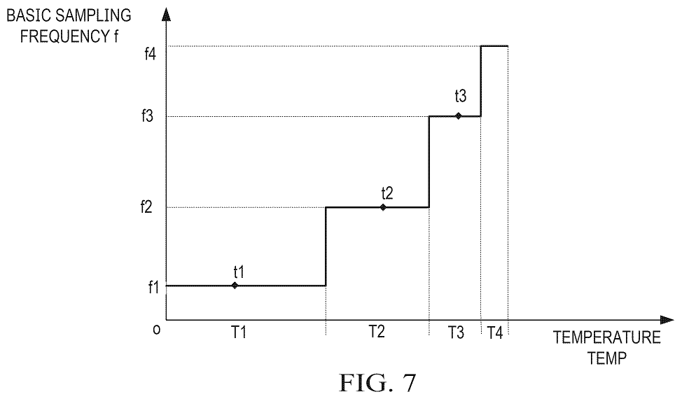

In one example, referring to FIG. 7, the possible temperature ranges of the target device include temperature interval T1, temperature interval T2, temperature interval T3 and temperature interval T4, in which the temperature increases sequentially, wherein the basic sampling frequency corresponding to the temperature interval T1 is f1, the basic sampling frequency corresponding to the temperature interval T2 is f2, the basic sampling frequency corresponding to the temperature interval T3 is f3, the basic sampling frequency corresponding to the temperature interval T4 is f4, and f4>f3>f2 greater than f1.

In one example, when the temperature of the target device rises from the first temperature interval to the second temperature interval, e.g., rises from the temperature in temperature interval T1 (e.g., t1) to the temperature in temperature interval T2 (e.g., t2), the corresponding basic sampling frequency also increases from f1 to f2.

Alternatively, when the temperature of the target device increases from the temperature in the temperature interval T2 (e.g., t2) to the temperature in the temperature interval T3 (e.g., t3), the corresponding basic sampling frequency also increases from f2 to f3.

In one example, in a possible implementation, the change rate of the basic sampling frequency from the temperature interval T2 to the temperature interval T3 is greater than the change rate of the basic sampling frequency from the temperature interval T1 to the temperature interval T2.

It should be noted that the range of the temperature interval may be reduced as the temperature increases, so that, after the temperature of the target device exceeds the normal operating temperature value, changes in the basic sampling frequency may respond to temperature changes more timely.

In one example, when the temperature of the target device exceeds the normal operating temperature interval T2, the ranges of the temperature interval T3 and the temperature interval T4 decrease successively, but the change value of the basic sampling frequency is the same.

It should be noted that the corresponding relationships between the temperatures and the basic sampling frequencies of different target devices are different. That is, the corresponding relationship between the memory controller's own temperature and the basic sampling frequency of the corresponding thermal throttling module is different from the corresponding relationship between the memory's own temperature and the basic sampling frequency of the corresponding thermal throttling module, and the corresponding relationship between the temperature of the target device and the basic sampling frequency of the corresponding thermal throttling module may not only be a linear relationship, but also a non-linear relationship, e.g., an exponential relationship, etc., which is not limited by the present disclosure.

For a memory controller and a memory, due to their different layout locations and functions, the impact element for thermal samplings that affect their sampling frequencies are also different. The impact factor of the memory controller includes a rate of temperature change, and the impact factor of the memory includes a rate of temperature change, a first position parameter, a second position parameter, the number of cycles of program/erase, the number of bad blocks and a type of stored data, etc.

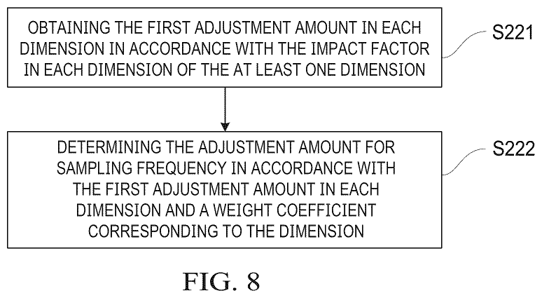

Referring to FIG. 8, in a possible implementation, calculating the adjustment amount for sampling frequency in accordance with the impact factor described above may include the following sub-operations:

S221: obtaining the first adjustment amount in each dimension in accordance with the impact factor in each dimension of the at least one dimension;

S222: determining the adjustment amount for sampling frequency in accordance with the first adjustment amount in each dimension and a weight coefficient corresponding to the dimension, wherein the adjustment amount for sampling frequency is equal to an accumulated value of the product of the first adjustment amount corresponding to each dimension of the at least one dimension and the corresponding weight coefficient.

For the impact factor in each dimension, a corresponding calculation is performed to obtain the first adjustment amount in the dimension. The first adjustment amount reflects the degree to which the impact factor of this dimension affect the sampling frequency, while the weight coefficient determines the relative importance of each dimension, then the final adjustment amount for sampling frequency is obtained by weighting and combining these first adjustment amounts with the weight coefficient. It should be noted that the weight coefficient corresponding to each dimension needs to be determined according to the actual application scenario, which is not limited by the present disclosure.

In one example, for the impact factor i in each dimension, the corresponding first adjustment amount Aᵢₗ is calculated. This adjustment amount represents the degree of impact of this dimension on the sampling frequency, which may be a positive number or a negative number, depending on the directionality of the impact factor, that is, the impact of the impact factor on the sampling frequency includes two directions: positive and negative, and when the impact is in the positive direction, the first adjustment amount Aᵢₗ is a positive number, when the impact is in the negative direction, the first adjustment amount Aᵢₗ is a negative number. For each dimension i, its corresponding first adjustment amount Aᵢₗ is multiplied by the weight coefficient Wᵢ to obtain the partial adjustment amount Pᵢ, that is, Pᵢ=Aᵢₗ×Wᵢ. This operation reflects the relative importance of the adjustment amounts in different dimensions, and the weight coefficients are used to adjust the degree of their impacts. Finally, all partial adjustments Pᵢ are added up to obtain the final adjustment amount for sampling frequency ΔF, i.e.,

$$Δ F = {\sum }_{i = 1}^{n} {P}_{i}$$

where n represents the number of dimensions.

The process described above implements the calculation of the dynamic adjustment amount of the sampling frequency in accordance with the impact factors and weight coefficients in multiple dimensions. The first adjustment amount in each dimension represents the contribution of that dimension to the sampling frequency, while the weight coefficient determines the relative importance of each dimension. By combining these adjustment amounts together, more complex adjustment strategies for sampling frequency may be implemented in accordance with multiple dimensions of impact factors.

Regarding the impact factor in the dimension of the rate of temperature change, in an aspect, the operating temperature of the memory controller may directly affect its performance, and a faster rate of temperature change may cause the temperature of the memory controller to rise or fall quickly, which may cause performance fluctuations. For example, when temperature rises, a memory controller may slow down its processing to prevent overheating, which may cause performance degradation. In another aspect, drastic changes in temperature may cause thermal stress within the memory controller, which may increase the risk of failure.

For a memory, in an aspect, NAND flash memory and random access memory are very sensitive to the rate of temperature change, and a rapid temperature change may cause the charge state of a memory cell to change, further causing data corruption or loss. In another aspect, the lifespan of a memory is temperature dependent. Rapid temperature changes may accelerate the wearing of the memory, resulting in a reduced lifespan for memory.

Therefore, the rate of temperature change is a critical impact factor that may have a significant impact on the performance, reliability, and lifespan of a memory controller and a memory. Therefore, dynamically adjusting the sampling frequency of the thermal throttling module in accordance with the rate of temperature change is critical for ensuring that the memory may provide optimal performance and reliability under various operating conditions.

In a possible implementation, the implementation of determining the first adjustment amount in the dimension of rate of temperature change may be: when the rate of temperature change increases, the first adjustment amount corresponding to the rate of temperature change is increased.

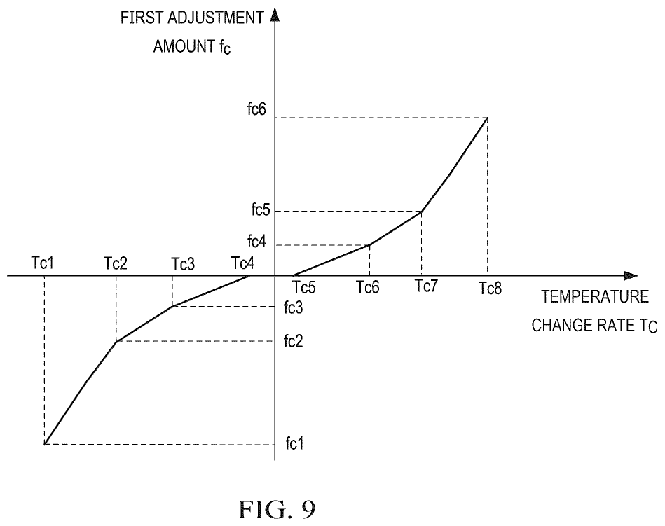

In one example, referring to FIG. 9, when the rate of temperature change of the target device exceeds the threshold Tc5 and gradually increases to Tc6, the corresponding first adjustment amount also gradually increases from 0 to fc4, and when the rate of temperature change continues to increase from Tc6 to Tc7, the corresponding first adjustment amount also gradually increases from fc4 to fc5. When the rate of temperature change continues to increase from Tc7 to Tc8, the corresponding first adjustment amount also gradually increases from fc5 to fc6. When the rate of temperature change increases from Tc5 to Tc6, the increase value is ΔTc1, the corresponding first adjustment amount is Δfc1. When the rate of temperature change increases from Tc6 to Tc7, the increase value is ΔTc2, the corresponding first adjustment amount is Δfc2. When the rate of temperature change increases from Tc7 to Tc8, the increase value is ΔTc3, the corresponding first adjustment amount is Δfc3. It may be seen that ΔTc1 is equal to ΔTc2 and ΔTc3, Δfc1 is less than Δfc2, and Δfc2 is less than Δfc3. That is, the first adjustment amount increases as the rate of temperature change increases, and as the rate of temperature change increases, the increasing tendency of the first adjustment amount also increases as the rate of temperature change increases.

Regarding the impact factor in the dimension of the first position parameter, the first position parameter is to represent the relative distance between the memory and the memory controller, and in the case that the temperature of the memory controller is high, when the first position parameter changes, the temperature of the memory may be affected. The distance between the memory and the memory controller affects the speed of heat conduction. If the memory is close to the memory controller, heat may transfer from the memory controller to the memory more quickly, causing the memory temperature to rise. This effect is more significant when the temperature of the memory controller is higher.

Therefore, the temperature of the memory decreases as a distance from the memory controller increases. If the memory is close to the memory controller, it may experience larger temperature gradients. This means that one part of the memory may be at a higher temperature, while another part may be at a lower temperature. Therefore, the sampling frequency of the thermal throttling module needs to be dynamically adjusted in accordance with the first position parameter.

In a possible implementation, the implementation of calculating the first adjustment amount in the dimension of the first position parameter may be: increasing the first adjustment amount corresponding to the first position parameter when the first position parameter decreases.

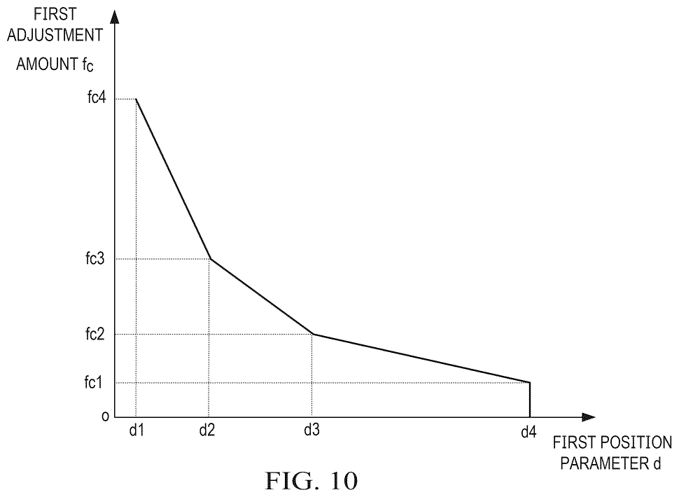

In one example, referring to FIG. 10, when the relative distance between the memory and the memory controller exceeds the threshold d1 and gradually increases to d2, the corresponding first adjustment amount also gradually decreases from fc4 to fc3, and when a position parameter continues to increase from d2 to d3, the corresponding first adjustment amount also gradually decreases from fc3 to fc2. When the relative distance increases from d1 to d2, the increase value is Δd1, the corresponding first adjustment amount is Δfc1. When the relative distance increases from d2 to d3, the increase value is Δd2, the corresponding first adjustment amount is Δfc2. It may be seen that Δd1 is equal to Δd2, and Δfc1 is greater than Δfc2. That is, the first adjustment amount decreases as the first position parameter increases, and as the first position parameter increases, the decrease tendency of the first adjustment amount also decreases.

Regarding the impact factor in the dimension of the second position parameter, the second position parameter is to represent the relative distance between the memory in the electronic device and the high-temperature area within the electronic device, the memory is usually installed inside an electronic device, and this location may vary depending on the design and layout of the electronic device, and due to the space inside the electronic device and the speed and direction of the heat dissipation airflow, memories in different locations may also exhibit different heat characteristics. A high-temperature area refers to certain areas inside an electronic device where the temperature is usually high because of a large amount of heat generated by certain components in the electronic device, e.g., the location of the power module or CPU of the electronic device. If the memory is located near a high-temperature area, some parts of the memory may be more susceptible to heat, while other parts may be relatively cooler. This may cause temperature gradients within the memory, affecting performance and reliability of the memory. Moreover, temperature of a memory has a greater impact on its lifespan, the memory close to the high-temperature area may wear out and age faster, therefore, it is required to dynamically adjust the sampling frequency of the thermal throttling module corresponding to the memory in accordance with the second position parameter.

In a possible implementation, the second position parameter is to represent the relative distance between the memory in the electronic device and a high-temperature area within the electronic device, the implementation of calculating the second adjustment amount in the dimension of the first position parameter may be: increasing the first adjustment amount corresponding to the second position parameter when the second position parameter decreases.

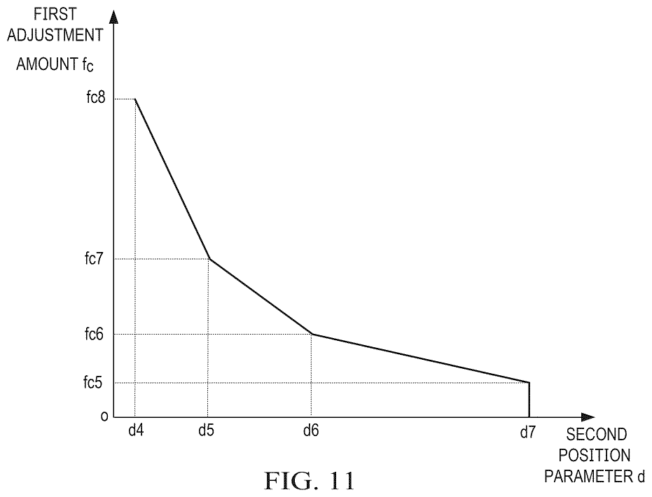

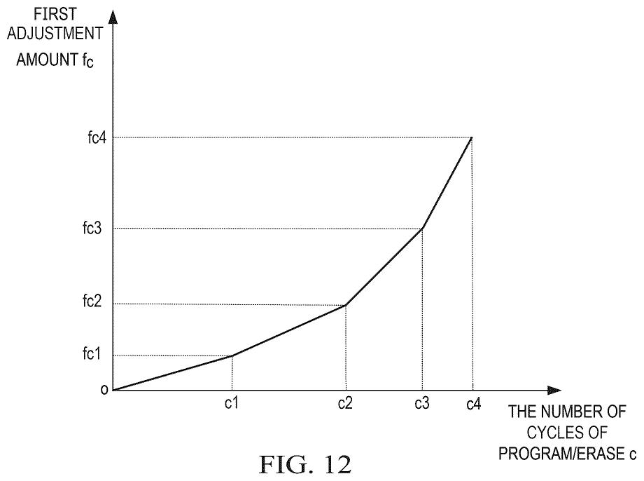

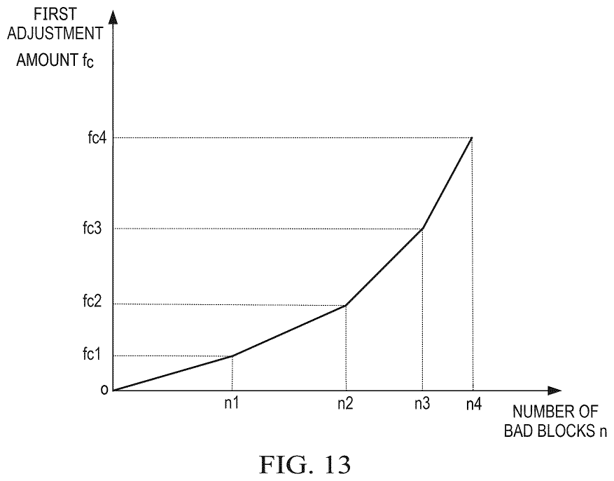

In one example, referring to FIG. 11, when the relative distance between the memory and the high-temperature area in the electronic device exceeds the threshold d4 and gradually increases to d5, the corresponding first adjustment amount also gradually decreases from fc8 to fc7, and when the relative distance between the memory and the high-temperature area in the electronic device continues to increase from d5 to d6, the corresponding first adjustment amount also gradually decreases from fc7 to fc6. When the relative distance increases from d4 to d5, the increase value is Δd1, the corresponding first adjustment amount is Δfc1. When the relative distance between the memory and the high-temperature area in the electronic device increases from d5 to d6, the increase value is Δd2, the corresponding first adjustment amount is Δfc2. It may be seen that Δd1 is equal to Δd2 and Δfc1 is greater than Δfc2. That is, the first adjustment amount decreases as the second position parameter increases, and as the second position parameter increases, the decrease tendency of the first adjustment amount decreases as the change rate of the second position parameter increases.

The changing trends of the corresponding relationship between the first position parameter and its corresponding first adjustment amount and the corresponding relationship between the second position parameter and its corresponding first adjustment amount may be the same or different, which needs to be determined according to actual usage conditions, and will not be limited by the present disclosure.

Regarding the impact factor in the dimension of the number of cycles of program/erase (PE Cycle), the number of cycles of program/erase is to represent how many write and erase operations has been performed on the memory, and a memory with a large number of the number of cycles of program/erases has been performed a large number of write and erase operations, which may cause wearing and charge state change of memory cells. And as the number of cycles of program/erase increases, the data stability of the memory may decrease, because the memory cells become more susceptible to bit flips or data corruption. Therefore, the sampling frequency of the thermal throttling module needs to be dynamically adjusted in accordance with the number of cycles of program/erase of a memory cell.

In a possible implementation, the implementation of calculating the first adjustment amount in the dimension of the number of cycles of program/erase times may be: increasing the first adjustment amount corresponding to the number of cycles of program/erase when the number of cycles of program/erase increases.

In one example, referring to FIG. 9, when the number of cycles of program/erase of a memory exceeds the preset threshold and gradually increases to c1, the corresponding first adjustment amount also gradually increases from 0 to fc1, and when the number of cycles of program/erase continues to increase from c1 to c2, the corresponding first adjustment amount also gradually increases from fc1 to fc2. When the number of cycles of program/erase continues to increase from c2 to c3, the corresponding first adjustment amount also gradually increases from fc2 to fc3. When the number of cycles of program/erase increases from 0 to c1, the increase value is Δc1, the corresponding first adjustment amount is Δfc1. When the number of cycles of program/erase increases from c1 to c2, the increase value is Δc2, the corresponding first adjustment amount is Δfc2. When the number of cycles of program/erase increases from c2 to c3, the increase value is Δc3, the corresponding first adjustment amount is Δfc3. It may be seen that Δc1 is equal to Δc2 and Δc3, Δfc1 is less than Δfc2, and Δfc2 is less than Δfc3. That is, the first adjustment amount increases as the number of cycles of program/erase increases, and as the number of cycles of program/erase increases, the first adjustment amount also increases as the tendency of the number of cycles of program/erase increases.

Regarding the impact factor in the dimension of the number of bad blocks, a bad block is a memory block in the memory that cannot be read or written normally. The presence of bad blocks increases data instability as they may cause data loss or inaccessibility. The presence of fewer bad blocks on memory generally means that the data stored by the memory is more reliable because there are more blocks available in the memory's capacity. For a memory with fewer bad blocks, there is a greater chance to perform more read and write tasks. Because more blocks are available, data stability is higher. Therefore, the sampling frequency needs to be dynamically adjusted in accordance with the number of bad blocks.

In a possible implementation, the implementation of calculating the first adjustment amount in the dimension of the number of bad blocks may be: increasing the first adjustment amount corresponding to the impact factor of the number of bad blocks when the number of bad blocks increases.

In one example, referring to FIG. 13, when the number of bad blocks of a memory exceeds the preset threshold and gradually increases to n1, the corresponding first adjustment amount also gradually increases from 0 to fc1, and when the number of bad blocks continues to increase from n1 to n2, the corresponding first adjustment amount also gradually increases from fc1 to fc2. When the number of bad blocks continues to increase from n2 to n3, the corresponding first adjustment amount also gradually increases from fc2 to fc3. When the number of bad blocks increases from 0 to n1, the increase value is Δn1, the corresponding first adjustment amount is Δfc1. When the number of bad blocks increases from n1 to n2, the increase value is Δn2, the corresponding first adjustment amount is Δfc2. When the number of bad blocks increases from n2 to n3, the increase value is Δn3, the corresponding first adjustment amount is Δfc3. It may be seen that Δn1 is equal to Δn2 and Δn3, Δfc1 is less than Δfc2, and Δfc2 is less than Δfc3. That is, the first adjustment amount increases as the number of bad blocks increases, and as the number of bad blocks increases, the first adjustment amount also increases as the tendency of the number of bad blocks increases.

Regarding the impact factor in the dimension of the type of stored data, the data stored in the memory may include two types: cold data and hot data, and due to the impact of data locality, when some data is read or written, they may be accessed again within a short period of time. This results in a small portion of the data being accessed frequently, while other data is accessed relatively less, i.e., data read and write operations may tend to be concentrated on the memory containing hot data. Therefore, in order to manage the memory better, the sampling frequency of the thermal throttling module needs to be dynamically adjusted in accordance with the type of data stored in the memory.

In a possible implementation, the implementation of calculating the first adjustment amount in the dimension of the type of stored data may be: increasing the first adjustment amount corresponding to the type of stored data when the type of stored data is hot data.

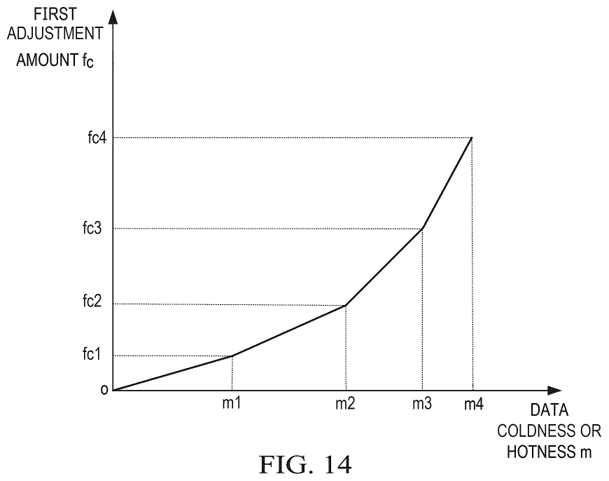

In one example, referring to FIG. 14, when the data coldness or hotness of a memory exceeds the preset threshold and gradually increases to m1, the corresponding first adjustment amount also gradually increases from 0 to fc1, and when the data coldness or hotness continues to increase from m1 to m2, the corresponding first adjustment amount also gradually increases from fc1 to fc2. When the data coldness or hotness continues to increase from m2 to m3, the corresponding first adjustment amount also gradually increases from fc2 to fc3. When the data coldness or hotness increases from 0 to m1, the increase value is Δm1, the corresponding first adjustment amount is Δfc1. When the data coldness or hotness increases from m1 to m2, the increase value is Δm2, the corresponding first adjustment amount is Δfc2. When the data coldness or hotness increases from m2 to m3, the increase value is Δm3, the corresponding first adjustment amount is Δfc3. It may be seen that Δm1 is equal to Δm2 and Δm3, Δfc1 is less than Δfc2, and Δfc2 is less than Δfc3. That is, the first adjustment amount increases as the data coldness or hotness increases, and as the data coldness or hotness increases, the first adjustment amount also increases as the tendency of the data coldness or hotness increases.

In one possible implementation, when considering impact factors of the sampling frequency, in addition to the factors mentioned above, different types of read and write operations performed by the solid-state drive may also be taken into consideration as another important impact element. A solid-state drive may usually perform a variety of read and write operations, e.g., sequential read and write, random read and write, and 4K read and write, etc. These different types of read and write operations may affect the workload, performance, and temperature of the solid-state drive in different degrees, therefore, the sampling frequency of the thermal throttling module may be dynamically adjusted in accordance with the current read and write types to more effectively manage temperature and optimize performance.

In one example, different types of read and write operations may cause different workloads on the internal chips of the solid-state drive. For example, sequential read and write usually involves sequential read and write of large blocks of data, while random read and write involves random read and write of small blocks of data. These different workloads result in different heat generation and distribution of the chip, which has an impact on the temperature profile. Therefore, the sampling frequency may be dynamically adjusted according to different types of read and write operations performed by the solid-state drive, which may allow for more precise management of temperature, optimizing performance, extending lifespan of the drive, and improving the stability and reliability of system.

In a possible implementation, in addition to the impact elements described above, the type of background task performed by the electronic device may also be used as the impact factor of the sampling frequency. A background task may cause change in the internal load of the solid state drive. Therefore, the sampling frequency of the thermal throttling module may be adjusted according to different types of background tasks to better adapt to changes in system load.

The method for adjusting sampling frequency provided by an example of the present disclosure firstly intelligently adjusts the sampling frequency of the thermal throttling module in accordance with the impact element for thermal sampling of the target device. Thus, when the solid-state drive responds to a large number of IO requests, temperature monitoring and thermal throttling may be dynamically optimized to more effectively maintain the stability and performance of system. Secondly, by adjusting the sampling frequency in accordance with impact elements for thermal sampling, the system may monitor and respond to temperature changes inside the solid state drive more accurately. This helps reduce the potential impact of high temperatures on the solid-state drive and reduces the possibility of data damage and data loss. By intelligently adjusting the sampling frequency, the system may reduce the rate of wearing and degradation of critical components within the solid-state drive. This may extend the lifespan of the solid-state drive and reduce maintenance and replacement costs.

In addition, the method for adjusting sampling frequency provided by the present disclosure adjusts the sampling frequency of the thermal throttling module corresponding to the target device to the target sampling frequency in accordance with the basic sampling frequency and the adjustment amount for sampling frequency, thereby implementing more refined sampling frequency management. The more refined sampling frequency management implements higher reliability, lower energy consumption and longer hardware lifespan by intelligently and adaptively adjusting monitoring and protection mechanisms.

It should be noted that the example described above takes a solid-state drive as an example for description, and the method of the present application may also be applied to other memory systems.

An example of the present disclosure also provides a memory system, including: a memory 112 and a memory controller 111; the memory controller 111 is coupled to the memory 112, and the memory controller 111 is configured to: obtain an impact element for thermal sampling of a target device; adjust the sampling frequency of the thermal throttling module corresponding to the target device in accordance with the impact element for thermal sampling.

In some examples, the impact element for thermal sampling includes the temperature of the target device and an impact factor in at least one dimension, the memory controller 111 is configured to: determine a basic sampling frequency in accordance with the temperature of the target device; determine the adjustment amount for sampling frequency in accordance with the impact factor in at least one dimension; adjust the sampling frequency of the thermal throttling module corresponding to the target device to the target sampling frequency in accordance with the basic sampling frequency and the adjustment amount for sampling frequency, wherein the target sampling frequency is equal to the sum of the basic sampling frequency and the adjustment amount for frequency.

In some examples, the memory controller 111 is configured to: determine the basic sampling frequency to be a first sampling frequency when the temperature of the target device is within a first temperature interval; determine the basic sampling frequency to be a second sampling frequency when the temperature of the target device is within a second temperature interval, wherein the temperature in the first temperature interval is lower than the temperature in the second temperature interval, and the first sampling frequency is lower than the second sampling frequency.

In some examples, the memory controller 111 is configured to: obtain the first adjustment amount in each dimension in accordance with the impact factor in each dimension of the at least one dimension; determine the adjustment amount for sampling frequency in accordance with the first adjustment amount in each dimension and a weight coefficient corresponding to the dimension, wherein the adjustment amount for sampling frequency is equal to an accumulated value of the product of the first adjustment amount corresponding to each dimension of the at least one dimension and the corresponding weight coefficient.

In some examples, the target device includes a memory controller 111 and a memory 112, wherein the impact factor of the memory controller 111 includes a rate of temperature change, and the impact factor of the memory 112 includes a rate of temperature change, a first position parameter, a second position parameter, the number of cycles of program/erase, the number of bad blocks and a type of hotness or coldness of stored data.

In some examples, the first position parameter is to represent a relative distance between the memory 112 and the memory controller 111, and the second position parameter is to represent a relative distance between the memory 112 and the high-temperature area in the electronic device.

In some examples, the memory controller 111 is configured to: increase the first adjustment amount corresponding to the rate of temperature change when the rate of temperature change increases.

In some examples, the memory controller 111 is further configured to: increase the first adjustment amount corresponding to the first position parameter when the first position parameter decreases.

In some examples, the memory controller 111 is further configured to: increase the first adjustment amount corresponding to the second position parameter when the second position parameter decreases.

In some examples, the memory controller 111 is further configured to: increase the first adjustment amount corresponding to the number of cycles of program/erase when the number of cycles of program/erase increases.

In some examples, the memory controller 111 is configured to: increase the first adjustment amount corresponding to the number of bad blocks when the number of bad blocks increases.

In some examples, the memory controller 111 is further configured to: increase the first adjustment amount corresponding to the impact factor of the type of hotness or coldness of stored data when the stored data is hot data.

An example of the present disclosure also provides an electronic device, the electronic device includes a host and a foregoing memory system, the host is connected to the memory system and is to store data into the memory system or read data from the memory system. In one example, the electronic device may be an electronic device shown in FIG. 1 in the foregoing example.

Those skilled in the art can clearly understand that, for the convenience and simplicity of description, in the examples described above, each example has its own emphasis in description, and for a part that are not described in detail in a certain example, reference may be made to the corresponding process in a foregoing method example, which will not be repeated here.

In the several examples provided by this disclosure, it should be understood that the provided adjustment for sampling frequency may be implemented in other ways. For example, the division of a certain module is only a logical function division, and in actual implementation, there may be other division methods, such as multiple elements or components may be combined, or may be integrated into another system, or some features may be ignored, or not implemented.

Those of ordinary skill in the art may realize that the modules and algorithm operations of each example described in conjunction with the examples disclosed herein may be implemented with electronic hardware, or a combination of computer software and electronic hardware. Whether these functions are performed in hardware or software depends on the specific application and design constraints of the technical solution. Those of ordinary skill in the art may implement the described functionality by using different methods for each specific application, but such implementations should not be considered to be beyond the scope of this disclosure.

The above is only specific implementations of the present disclosure, but the claimed scope of the present disclosure is not limited thereto, and changes or substitutions within the technical scope disclosed in the present disclosure that may be easily conceived by those skilled in the art shall fall within the claimed scope of the present disclosure. Therefore, the claimed scope of the present disclosure should be determined by the claimed scope of the claims.

What is claimed is:

1. A method for adjusting sampling frequency, including:
obtaining an impact element for thermal sampling of a target device; and
adjusting a sampling frequency of a thermal throttling module corresponding to the target device in accordance with the impact element for thermal sampling.

2. The method of claim 1, wherein the impact element for thermal sampling includes a temperature of the target device and an impact factor in at least one dimension; and the adjusting a sampling frequency of a thermal throttling module corresponding to the target device in accordance with the impact element for thermal sampling includes:
determining a basic sampling frequency in accordance with the temperature of the target device;
determining an adjustment amount for sampling frequency in accordance with an impact factor in the at least one dimension; and
adjusting the sampling frequency of the thermal throttling module corresponding to the target device to a target sampling frequency in accordance with the basic sampling frequency and the adjustment amount for sampling frequency, wherein the target sampling frequency is equal to a sum of the basic sampling frequency and the adjustment amount for sampling frequency.

3. The method of claim 2, wherein the determining a basic sampling frequency in accordance with the temperature of the target device includes:
determining the basic sampling frequency to be a first sampling frequency when the temperature of the target device is within a first temperature interval; and
determining the basic sampling frequency to be a second sampling frequency when the temperature of the target device is within a second temperature interval;
wherein the temperature in the first temperature interval is lower than the temperature in the second temperature interval, and the first sampling frequency is lower than the second sampling frequency.

4. The method of claim 2, wherein the determining an adjustment amount for sampling frequency in accordance with the impact factor in the at least one dimension includes:
obtaining a first adjustment amount in each dimension in accordance with the impact factor in each dimension of the at least one dimension; and
determining the adjustment amount for sampling frequency in accordance with the first adjustment amount in each dimension and a weight coefficient corresponding to the dimension, wherein the adjustment amount for sampling frequency is equal to an accumulated value of a product of a first adjustment amount corresponding to each dimension of the at least one dimension and a corresponding weight coefficient.

5. The method of claim 4, wherein the target device includes a memory controller and a memory, wherein an impact factor of the memory controller includes a rate of temperature change, and an impact factor of the memory includes a rate of temperature change, a first position parameter, a second position parameter, a number of cycles of program/erase, a number of bad blocks and a type of stored data.

6. The method of claim 5, wherein the first position parameter is to represent a relative distance between the memory and the memory controller, and the second position parameter is to represent a relative distance between the memory and a high-temperature area in an electronic device.

7. The method of claim 5, wherein the obtaining a first adjustment amount in each dimension in accordance with the impact factor in each dimension includes:
increasing a first adjustment amount corresponding to the rate of temperature change when the rate of temperature change increases.

8. The method of claim 5, wherein the obtaining a first adjustment amount in each dimension in accordance with the impact factor in each dimension further includes:
increasing a first adjustment amount corresponding to the first position parameter when the first position parameter decreases.

9. The method of claim 5, wherein the obtaining a first adjustment amount in each dimension in accordance with the impact factor in each dimension further includes:
increasing a first adjustment amount corresponding to the second position parameter when the second position parameter decreases.

10. The method of claim 5, wherein the obtaining a first adjustment amount in each dimension in accordance with the impact factor in each dimension further includes:
increasing a first adjustment amount corresponding to the number of cycles of program/erase when the number of cycles of program/erase increases.

11. The method of claim 5, wherein the obtaining a first adjustment amount in each dimension in accordance with the impact factor in each dimension further includes:
increasing a first adjustment amount corresponding to the number of bad blocks when the number of bad blocks increases.

12. The method of claim 5, wherein the obtaining a first adjustment amount in each dimension in accordance with the impact factor in each dimension further includes:
increasing a first adjustment amount corresponding to the type of stored data when the type of stored data is hot data.

13. A memory system, including:
a memory; and
a memory controller, coupled to the memory and configured to:
obtain an impact element for thermal sampling of a target device; and
adjust a sampling frequency of a thermal throttling module corresponding to the target device in accordance with the impact element for thermal sampling.

14. The memory system of claim 13, wherein the impact element for thermal sampling includes a temperature of the target device and an impact factor in at least one dimension, the memory controller is configured to:
determine a basic sampling frequency in accordance with the temperature of the target device;
determine an adjustment amount for sampling frequency in accordance with the impact factor in the at least one dimension; and
adjust the sampling frequency of the thermal throttling module corresponding to the target device to a target sampling frequency in accordance with the basic sampling frequency and the adjustment amount for sampling frequency, wherein the target sampling frequency is equal to a sum of the basic sampling frequency and the adjustment amount for sampling frequency.

15. The memory system of claim 14, wherein the memory controller is configured to:
determine the basic sampling frequency to be a first sampling frequency when the temperature of the target device is within a first temperature interval; and
determine the basic sampling frequency to be a second sampling frequency when the temperature of the target device is within a second temperature interval;
wherein the temperature in the first temperature interval is lower than the temperature in the second temperature interval, and the first sampling frequency is lower than the second sampling frequency.

16. The memory system of claim 14, wherein the memory controller is configured to:
obtain a first adjustment amount in each dimension in accordance with the impact factor in each dimension of the at least one dimension; and
determine the adjustment amount for sampling frequency in accordance with the first adjustment amount in each dimension and a weight coefficient corresponding to the dimension, wherein the adjustment amount for sampling frequency is equal to an accumulated value of a product of a first adjustment amount corresponding to each dimension of the at least one dimension and a corresponding weight coefficient.

17. The memory system of claim 16, wherein the target device includes a memory controller and a memory, wherein an impact factor of the memory controller includes a rate of temperature change, and an impact factor of the memory includes a rate of temperature change, a first position parameter, a second position parameter, a number of cycles of program/erase, a number of bad blocks and a type of hotness or coldness of stored data.

18. The memory system of claim 17, wherein the first position parameter is to represent a relative distance between the memory and the memory controller, and the second position parameter is to represent a relative distance between the memory and a high-temperature area in an electronic device.

19. The memory system of claim 17, wherein the memory controller is configured to:
increase a first adjustment amount corresponding to the rate of temperature change when the rate of temperature change increases.

20. The memory system of claim 17, wherein the memory controller is further configured to:
increase a first adjustment amount corresponding to the first position parameter when the first position parameter decreases.

21. The memory system of claim 17, wherein the memory controller is further configured to:
increase a first adjustment amount corresponding to the second position parameter when the second position parameter decreases.

22. The memory system of claim 17, wherein the memory controller is further configured to:
increase a first adjustment amount corresponding to the number of cycles of program/erase when the number of cycles of program/erase increases.

23. The memory system of claim 17, wherein the memory controller is further configured to:
increase a first adjustment amount corresponding to the number of bad blocks when the number of bad blocks increases.

24. The memory system of claim 17, wherein the memory controller is further configured to:
increase a first adjustment amount corresponding to the impact factor of the type of hotness or coldness of stored data when the stored data is hot data.

25. An electronic device, including:
a memory system, including:
a memory; and
a memory controller, coupled to the memory and configured to:
obtain an impact element for thermal sampling of a target device; and
adjust a sampling frequency of a thermal throttling module corresponding to the target device in accordance with the impact element for thermal sampling; and
a host coupled with the memory system to write data to the memory system or read data stored in the memory system.
